(19) United States
(12) Patent Application Publication
(10) Pub. No.: US 2016/0093753 A1
(43) Pub. Date: Mar. 31, 2016

(54) SOLAR CELL MANUFACTURING METHOD

(71) Applicant: Panasonic Intellectual Property Management Co., Ltd., Osaka (JP)

(72) Inventors: Shoji SATO, Osaka (JP); Shigeharu TAIRA, Osaka (JP); Naohiro HITACHI, Osaka (JP); Akinao KITAHARA, Osaka (JP)

(21) Appl. No.: 14/867,639

(22) Filed: Sep. 28, 2015

(30) Foreign Application Priority Data
Sep. 29, 2014 (JP) 2014-198710
Mar. 20, 2015 (JP) 2015-058334

(51) Int. Cl. H01L 31/0224; H01L 21/66; H01L 31/18

(52) U.S. Cl. CPC H01L 31/022433; H01L 31/18; H01L 22/14

(57) ABSTRACT

There is provided a solar cell manufacturing method comprising: a step of preparing a photoelectric conversion cell having a first main surface and a second main surface; a step of forming a first collector electrode on the first main surface and forming a second collector electrode on the second main surface; a step of measuring characteristic values of the photoelectric conversion cell having the first collector electrode and the second collector electrode thereon; and a step of forming a third collector electrode on at least one of the first main surface and the second main surface based on the characteristic values.

### PRIORITY INFORMATION

The present invention claims priority under 35 U.S.C. §119 to Japanese Application No. 2014-198710, filed on Sep. 29, 2014 and No. 2015-058334, filed on Mar. 20, 2015, the entire contents of which are incorporated herein by reference.

### BACKGROUND OF THE INVENTION

1. Field of the Invention

The present disclosure relates to a solar cell manufacturing method.

2. Description of the Related Art

The solar cell includes a collector electrode formed on a surface thereof in order to output the power generated therein externally. Japanese Patent Laid-Open Publication No. Hei 11-103084 proposes a method of repeating screen printing a plurality of times at a collector electrode forming position to form the collector electrode.

As disclosed in Japanese Patent Laid-Open Publication No. Hei 11-103084, a solar cell is manufactured by repeating, a plurality of times, a process of forming a collector electrode on the same main surface of the solar cell, and if a solar cell does not exhibit desired properties, the solar cell may be discarded as scrap. Generally the collector electrode is made of expensive material such as silver. Therefore, unfavourably, a large amount of material for forming the collector electrode is used for the solar cells to be discarded.

It is an advantage of the present disclosure to provide a solar cell manufacturing method of manufacturing solar cells by repeating, a plurality of times, a process of forming collector electrodes, the method being capable of improving economic efficiency.

### SUMMARY OF THE INVENTION

The manufacturing method of the present disclosure comprises a step of preparing a photoelectric conversion cell having a first main surface and a second main surface; a step of forming a first collector electrode on the first main surface and forming a second collector electrode on the second main surface; a step of measuring characteristic values of the photoelectric conversion cell having the first collector electrode and the second collector electrode thereon; and a step of forming a third collector electrode on at least one of the first main surface and the second main surface based on the characteristic values.

According to an aspect of the present disclosure, the method of manufacturing solar cells by repeating, a plurality of times, a process of forming collector electrodes can improve economic efficiency.

### BRIEF DESCRIPTION OF THE DRAWINGS

FIG. 1 is a flowchart for describing a solar cell manufacturing method according to first and second embodiments;

FIG. 2 is a schematic plan view illustrating a first collector electrode provided on a first main surface of the solar cell according to the first and second embodiments;

FIG. 3 is a schematic plan view illustrating a second collector electrode provided on a second main surface of the solar cell according to the first and second embodiments;

FIG. 4 is a schematic cross-sectional view illustrating a partial section taken along line A-A in FIG. 2;

FIG. 5 is a schematic cross-sectional view illustrating a state in which a third collector electrode is formed so as to overlap the first collector electrode on the first main surface in the first embodiment;

FIG. 6 is a schematic plan view illustrating a state in which the third collector electrode having the same width as that of the first collector electrode is positionally shifted and overlappingly stacked on the first collector electrode in the first embodiment;

FIG. 7 is a schematic plan view illustrating a state in which the third collector electrode is overlappingly stacked on the first collector electrode that is narrower than the third collector electrode without being positionally shifted in the first embodiment;

FIG. 8 is a schematic plan view illustrating a state in which the third collector electrode is positionally shifted and overlappingly stacked on the first collector electrode that is narrower than the third collector electrode in the first embodiment;

FIG. 9 is a schematic plan view illustrating a state in which the third collector electrode that is narrower than the first collector electrode is overlappingly stacked on the first collector electrode without being positionally shifted in the second embodiment;

FIG. 10 is a schematic plan view illustrating a state in which the third collector electrode that is narrower than the first collector electrode is positionally shifted and overlappingly stacked on the first collector electrode in the second embodiment;

FIG. 11 is a view for describing an example of a method of measuring characteristic values of a photoelectric conversion cell;

FIG. 12 is a view for describing an example of a method of measuring the characteristic values of the photoelectric conversion cell;

FIG. 13 is a view for describing an example of a solar cell manufacturing method using an auxiliary electrode;

FIG. 14 is a view for describing an example of the solar cell manufacturing method using the auxiliary electrode;

FIG. 15 is a view illustrating a state in which the third collector electrode is connected to a busbar electrode;

FIG. 16 is a view for describing an example of a solar cell manufacturing method using a connection electrode; and

FIG. 17 is a view for describing an example of the solar cell manufacturing method using the connection electrode.

### DESCRIPTION OF PREFERRED EMBODIMENTS

Hereinafter, preferred embodiments will be described with reference to the accompanying drawings. Note that the following embodiments are merely illustrative and the present disclosure is not intended to be limited to the following embodiments. Note also that in each of the drawings, the components having substantially the same functions may be referred to with the same reference numerals or characters.

### First and Second Embodiments

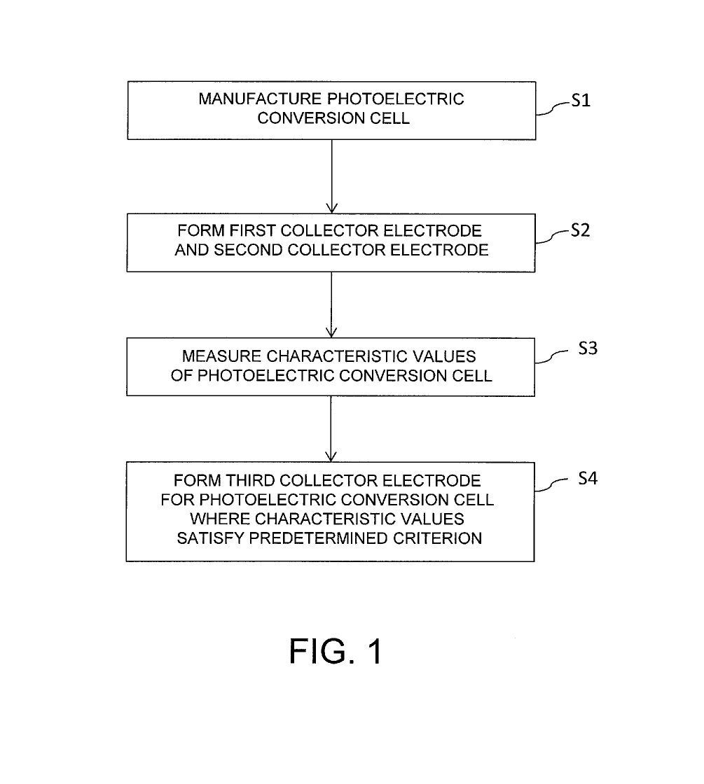

FIG. 1 is a flowchart for describing a solar cell manufacturing method according to first and second embodiments.

As illustrated in FIG. 1, a photoelectric conversion cell is manufactured in step S1. The photoelectric conversion cell can be manufactured in the same manner as a photoelectric conversion cell for a common solar cell. For example, one conductivity type amorphous semiconductor layer is formed on a first main surface side of another conductivity type semiconductor substrate, and a transparent conductive film is formed thereon. One conductivity type amorphous semiconductor layer is formed on a second main surface side, and a transparent conductive film is formed thereon. In the present embodiment, a p-type amorphous silicon layer and a transparent conductive film are formed on the first main surface side of an n-type crystalline silicon substrate, and an n-type amorphous silicon layer and a transparent conductive film are formed on the second main surface side. In the present embodiment, the p-type amorphous silicon layer has a layer structure in which an i-type amorphous silicon film and a p-type amorphous silicon film are formed in this order. In addition, the n-type amorphous silicon layer has a layer structure in which an i-type amorphous silicon film and an n-type amorphous silicon film are formed in this order.

In step S2, a first collector electrode is formed on the first main surface of the photoelectric conversion cell, namely, on the transparent conductive film on the first main surface side; and a second collector electrode is formed on the second main surface of the photoelectric conversion cell, namely, on the transparent conductive film on the second main surface side.

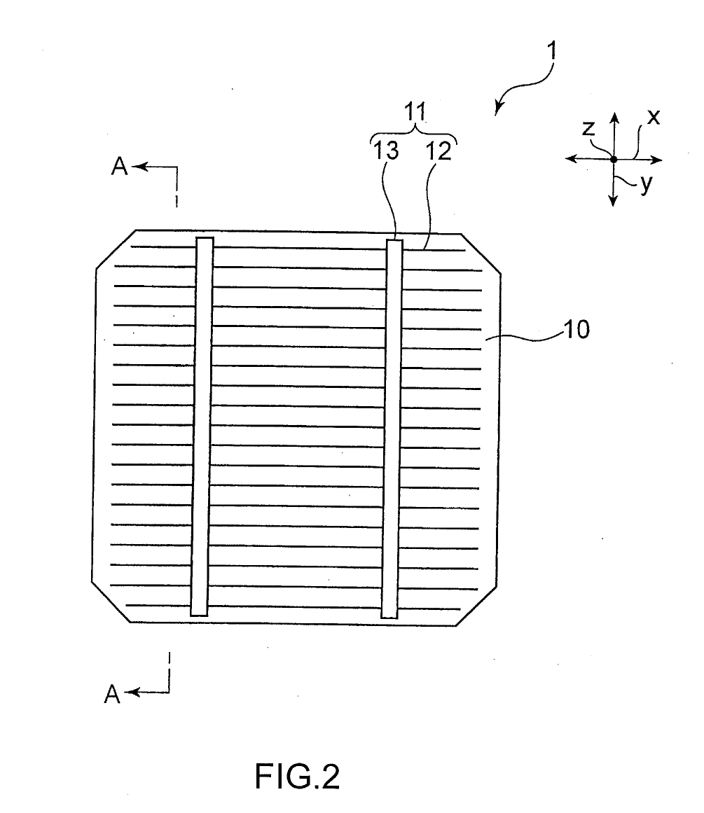

FIG. 2 is a schematic plan view illustrating the first collector electrode provided on the first main surface of the solar cell according to the first and second embodiments. As illustrated in FIG. 2, a first main surface 10 of a photoelectric conversion cell 1 includes thereon a first finger electrode 12 extending in a first direction (x direction), and a first busbar electrode 13 extending in a second direction (y direction) crossing the first direction. In the present embodiment, the first finger electrode 12 and the first bus bar electrode 13 constitute the first collector electrode 11.

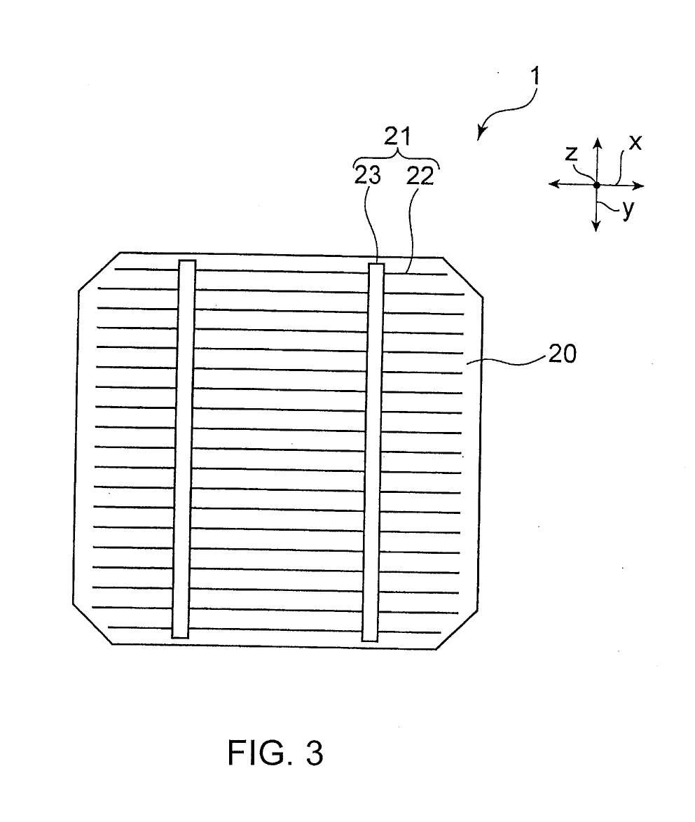

FIG. 3 is a schematic plan view illustrating the second collector electrode provided on the second main surface of the solar cell according to the first and second embodiments. As illustrated in FIG. 3, a second main surface 20 of the photoelectric conversion cell 1 includes thereon a second finger electrode 22 extending in the first direction (x direction) and a second bus bar electrode 23 extending in the second direction (y direction) crossing the first direction. In the present embodiment, the second finger electrode 22 and the second busbar electrode 23 constitute a second collector electrode 21.

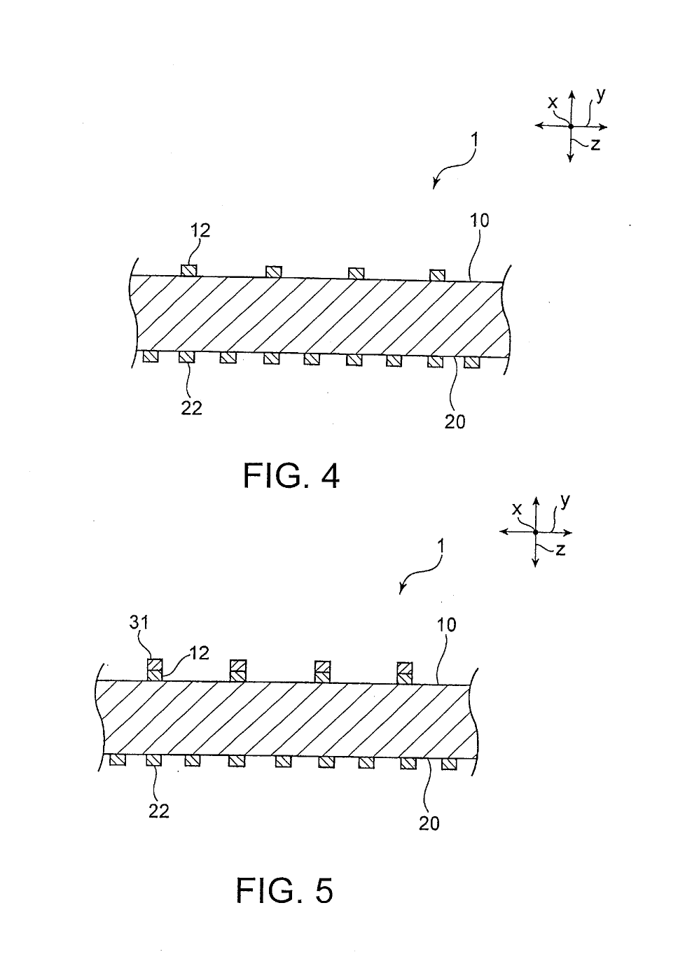

FIG. 4 is a schematic cross-sectional view illustrating a partial section taken along line A-A in FIG. 2. As illustrated in FIG. 4, in the present embodiment, the second finger electrode 22 is formed at a position corresponding to the first finger electrode 12. Further, the number of second finger electrodes 22 is greater than the number of first finger electrodes 12. However, the present disclosure is not limited to this, and the second finger electrode 22 may be formed at a position shifted from the position corresponding to the first finger electrode 12, and the number of first finger electrodes 12 may be the same as the number of second finger electrodes 22.

In the present embodiment, conductive paste containing silver particles and the like is subjected to screen printing, to thereby form the first collector electrode 11 and the second collector electrode 21. Note that the method is not limited to this, but another method such as inkjet printing and offset printing may be used to form the first collector electrode 11 and the second collector electrode 21. In the present embodiment, the first finger electrode 12 and the first busbar electrode 13 are integrally formed by screen printing. Likewise, the second finger electrode 22 and the second busbar electrode 23 are integrally formed by screen printing.

In the present embodiment, the first main surface 10 is a light receiving surface and the second main surface 20 is a rear surface. Note that the present disclosure is not limited to this, but may be a bifacial photoelectric conversion cell including the first main surface 10 and the second main surface 20, each of which is a light receiving surface.

Now referring back to FIG. 1, the first collector electrode 11 and the second collector electrode 21 are formed on the photoelectric conversion cell 1 as described above, and then the characteristic values of the photoelectric conversion cell 1 are measured and evaluated in step S3. For example, the characteristic values of the photoelectric conversion cell 1 can be measured according to JISC8913. Examples of the characteristic values to be measured include the characteristic values specified in JISC8913. The specific examples of the characteristic values include maximum output Pm, short-circuit current Isc, open circuit voltage Voc, fill factor FF, and solar cell conversion efficiency η. These characteristic values may be evaluated individually or may be evaluated in combination.

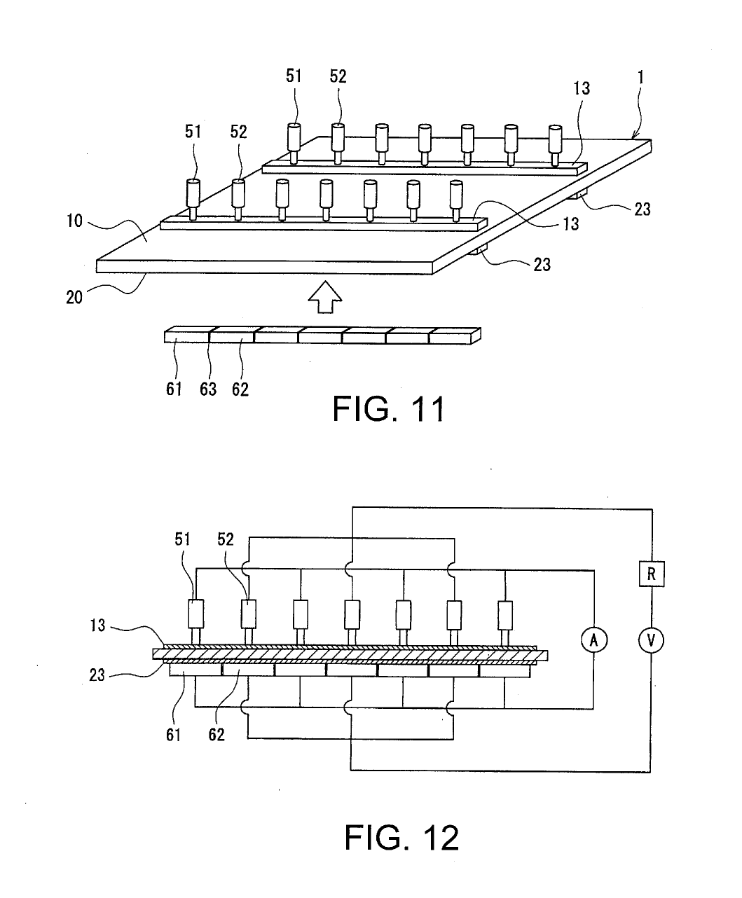

As illustrated in FIGS. 11 and 12, in step S3, preferably, the characteristic values are measured by a four-terminal method by brining a plurality of current measuring terminals 51 and 61 and a plurality of voltage measuring terminals 52 and 62 into contact with the first collector electrode 11 and the second collector electrode 21 respectively. Each terminal contacts the busbar electrodes 13 and 23, respectively. Note that if no busbar electrodes are provided, each terminal contacts, for example, the finger electrode. Each of the current measuring terminals 51 and 61 is connected to an ammeter, and each of the voltage measuring terminals 52 and 62 is connected to a voltmeter. The number of the plurality of current measuring terminals 51 and 61 and the plurality of voltage measuring terminals 52 and 62 installed may be three or more respectively.

Although the characteristic values can be measured by a two-terminal method, the application of the four-terminal method can reduce the influence of voltage drop due to contact resistance between a collector electrode and a terminal, cable resistance, and the like, and thus can suppress variations in the measured voltage. In other words, the application of the four-terminal method can improve measurement accuracy in the characteristic values. In addition, an increase in the number of terminals in a range not affecting the operation reduces variations in the measured voltage and improves standard deviation σ of the measured values of the fill factor FF.

In the examples illustrated in FIGS. 11 and 12, the current measuring terminal 51 and the voltage measuring terminal 52 contacting the first collector electrode 11 are pin-like terminals that can independently abut against the respective collector electrodes. Meanwhile, the current measuring terminal 61 and the voltage measuring terminal 62 contacting the second collector electrode 21 are block-like terminals where each of the blocks is alternately connected to each other with an insulator 63 interposed therebetween. The current measuring terminal 61 and the voltage measuring terminal 62 are aligned in a row to form a rod-like shape. The current measuring terminal 61 and the voltage measuring terminal 62 formed in rod-like terminals have a substantially flat surface facing the second collector electrode 21. Of the rod-like terminals, the surface facing the second collector electrode 21 continuously contacts the second collector electrode 21. Note that a pin-like terminal may contact one main surface side, and a rod-like terminal may contact the other main surface side. For example, a rod-like terminal may contact the first collector electrode 11, and a pin-like terminal may contact the second collector electrode 21. Note that the current measuring terminal 51 and the voltage measuring terminal 52 need not be arranged alternately every other terminal. For example, a group of five current measuring terminals 51 and one voltage measuring terminal 52 may be periodically alternately arranged. The current measuring terminal 61 and the voltage measuring terminal 62 may also be periodically alternately arranged. Using both the pin-like terminals and the rod-like terminals in this manner allows the characteristic values to be measured with high accuracy while suppressing cracking of the photoelectric conversion cell 1.

As illustrated in FIG. 12, when the first busbar electrode 13 (first collector electrode 11) is disposed on an upper surface in the vertical direction and the second busbar electrode 23 (second collector electrode 21) is disposed on a lower surface in the vertical direction, preferably, a pin-like terminal contacts the first busbar electrode 13 and a rod-like terminal contacts the second busbar electrode 23. In this case, the rod-like terminal contacts the second busbar electrode 23, and then the pin-like terminal contacts the first busbar electrode 13 before measuring the characteristic values. The pin-like terminals discretely contact the first busbar electrode 13 so as to generate a region contacting the pin-like terminal and a region not contacting the pin-like terminal, resulting uneven pressure being applied thereto. However, the pressure due to the pin-like terminals is dispersed by the substantially flat rod-like terminals disposed on the rear side and continuously contacting the second busbar electrode 23. This structure allows the characteristic values to be measured with good accuracy while suppressing cracking of the photoelectric conversion cell 1 due to the measurement in step S3.

As an alternative to the measurement device and the measurement method illustrated in FIG. 12, it can be considered to replace the measuring terminals on both sides contacting the first busbar electrode 13 and the second busbar electrode 23 with pin-like terminals including a plurality of terminals. However, if the measuring terminals on both sides are pin-like terminals, a difference may occur at a position on the plane of the photoelectric conversion cell 1 between a pin-like terminal contacting the first busbar electrode 13 and a pin-like terminal contacting the second busbar electrode 23. In this case, a high pressure is locally applied to the photoelectric conversion cell 1, and thus there is a possibility that cracking will occur in the photoelectric conversion cell 1. In addition, as an alternative to the measurement device and the measurement method illustrated in FIG. 12, it can be considered to replace the measuring terminals on both sides contacting the first busbar electrode 13 and the second busbar electrode 23 with rod-like terminals. Note that the photoelectric conversion cell 1 may include projecting portions and recessed portions in a range not affecting the power generation function. At this time, if the measuring terminals on both sides are rod-like terminals, a high pressure may be locally applied to the projecting portions of the photoelectric conversion cell 1 and thus there is a possibility that cracking will occur in the photoelectric conversion cell 1. Thus, employing the measurement device and the measurement method illustrated in FIG. 12 allows the characteristic values to be measured with high accuracy while suitably suppressing cracking of the photoelectric conversion cell 1.

A circuit connecting the voltage measuring terminals 52 and 62 to the voltmeter may include therein a resistor having a resistance greater than the resistance of the first collector electrode 11 and the second collector electrode 21 contacting the respective terminals, more specifically, the resistance of the busbar electrodes 13 and 23. This structure eliminates the influence of the resistance of the busbar electrodes 13 and 23 and further improves voltage measurement accuracy.

In step S4, based on the characteristic values measured in step S3, a third collector electrode is formed on at least one of the first main surface and the second main surface. For example, for the photoelectric conversion cell 1 where the characteristic values satisfy a predetermined criterion, a third collector electrode is formed on at least one of the first main surface and the second main surface. In the first and second embodiments to be described below, the third collector electrode is formed on the first main surface.

The third collector electrode can also be formed by subjecting conductive paste containing silver particles and the like to screen printing in the same manner as the first collector electrode 11 and the second collector electrode 21. Alternatively, the third collector electrode may be formed by another method such as inkjet printing and offset printing.

In the first and second embodiments, the third collector electrode is formed only for the photoelectric conversion cell 1 where the characteristic values measured in step S3 satisfy a predetermined criterion. Even if the third collector electrode is formed for the photoelectric conversion cell 1 where the characteristic values do not satisfy a predetermined criterion, a defective product is produced with high probability. The third collector electrode forming material can be saved from being wasted by preventing unnecessary third collector electrodes from being formed on a photoelectric conversion cell 1 that may be defective with high probability, which can increase economic efficiency. Note that step S4 may be applied to a photoelectric conversion cell 1 where the characteristic values do not satisfy a predetermined criterion. In this case, the power of a photoelectric conversion cell 1 with low maximum power can be increased and a greater number of photoelectric conversion cells 1 with high maximum power can be manufactured.

### First Embodiment

In the first embodiment, the third collector electrode is formed so as to at least partially overlap the first collector electrode of the first main surface.

FIG. 5 is a schematic cross-sectional view illustrating a state in which the third collector electrode is formed so as to overlap the first collector electrode on the first main surface in the first embodiment. Specifically, as illustrated in FIG. 5, the third collector electrode 31 is formed so as to overlap the first finger electrode 12 of the first collector electrode 11. Alternatively, the third collector electrode 31 may be formed so as to overlap the first busbar electrode 13 on the first busbar electrode 13 of the first collector electrode 11.

The surface of the collector electrode can be planarized by forming the third collector electrode 31 so as to at least partially overlap the first collector electrode 11. Thus, the thickness of the collector electrode can be increased, which reduces the electrical resistance of the first finger electrode 12 and increases current collecting properties.

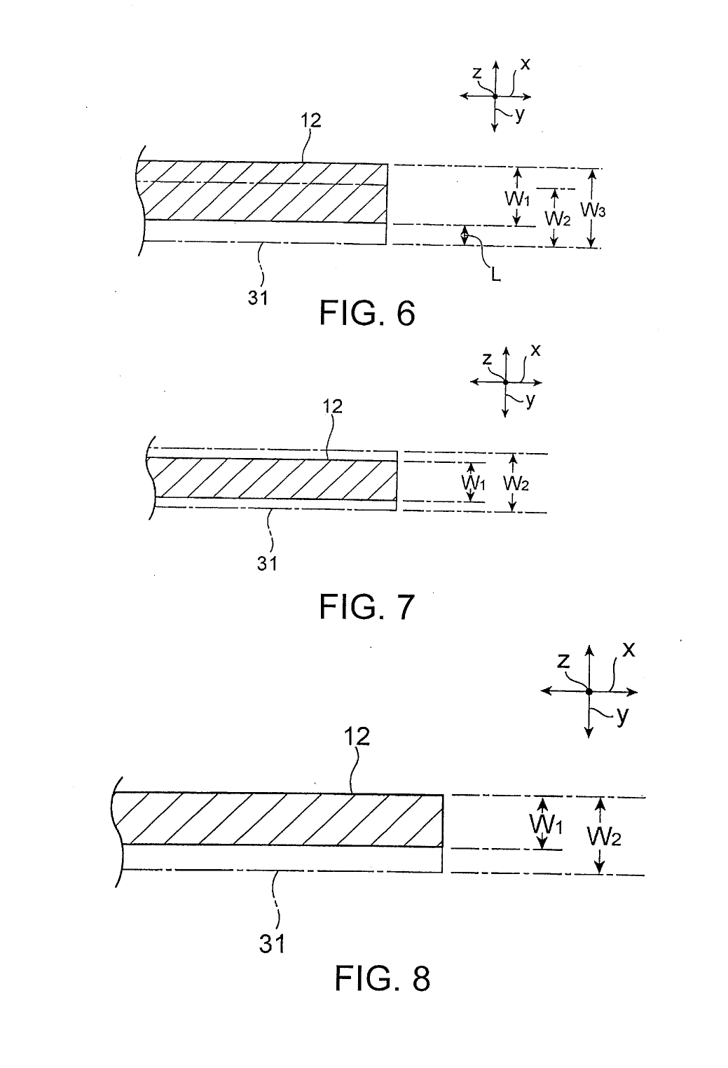

FIG. 6 is a schematic plan view illustrating a state in which the third collector electrode 31 is positionally shifted and overlappingly stacked on the first finger electrode 12 of the first collector electrode in the first embodiment. In FIG. 6, the third collector electrode 31 is indicated by dot-and-dash lines. In the following drawings, the third collector electrode 31 may be indicated by dot-and-dash lines.

The first finger electrode 12 has a width W1 in a second direction (y direction), which is substantially the same as a width W2 in the second direction (y direction) of the third collector electrode 31. As illustrated in FIG. 6, the third collector electrode 31 is formed to be shifted by a distance L in the second direction (y direction), resulting in the width of a collector electrode formed by stacking the third collector electrode 31 overlappingly on the first finger electrode 12 being increased to a width W3. Thus, the width W3 of the collector electrode is greater than the width W1 of the first finger electrode 12 and the width W2 of the third collector electrode 31, which increases the light-shielded area and reduces the short-circuit current Isc of the photoelectric conversion cell 1.

FIG. 7 is a schematic plan view illustrating a state in which the third collector electrode 31 is overlappingly stacked on the first finger electrode 12 having the width W1 that is less than the width W2 of the third collector electrode 31 without being positionally shifted in the first embodiment.

FIG. 8 is a schematic plan view illustrating a state in which the third collector electrode 31 illustrated in FIG. 7 is positionally shifted and overlappingly stacked on the first finger electrode 12. As illustrated in FIG. 8, the width W1 of the first finger electrode 12 is less than the width W2 of the third collector electrode 31. In this case, even if the third collector electrode 31 is positionally shifted, the stacked collector electrode is contained within the width W2, which prevents an increase in width of the positionally shifted and stacked collector electrode. Thus, this structure can reduce variations in width of the stacked collector electrode without being affected by the degrees of positional shifting of the third collector electrode 31.

The third collector electrode 31 is preferably configured to be disposed in a region near the busbar electrode 13 of the finger electrode 12 and not to be disposed in a region far from the busbar electrode 13. The region near the busbar electrode 13 of the finger electrode 12 receives current flowing from a region far from the busbar electrode 13 of the finger electrode 12 and current collected in a region near the busbar electrode 13. Thus, the region near the busbar electrode 13 of the finger electrode 12 has a higher current density than that of the region far from the busbar electrode 13 of the finger electrode 12, and thus there is possibility of causing resistance loss and reducing current collecting properties. A partial increase in thickness of the finger electrode 12 in a region near the busbar electrode 13 can reduce electrical resistance in a region with high current density while saving the amount of formation material.

### Second Embodiment

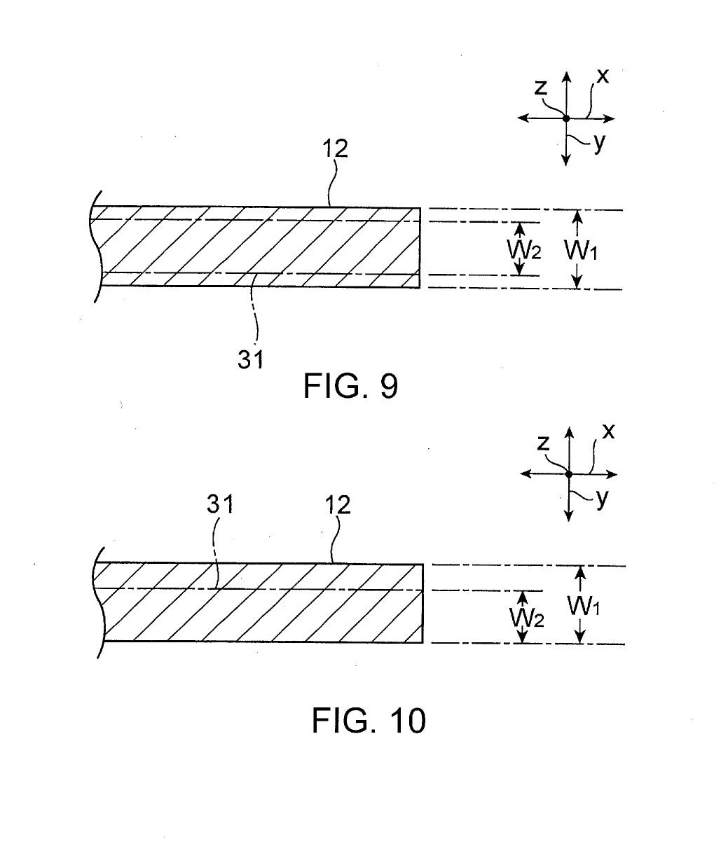

FIG. 9 is a schematic plan view illustrating a state in which the third collector electrode 31 having the width W2 that is less than the width W1 of the first finger electrode 12 is overlappingly stacked on the first finger electrode 12 without being positionally shifted in the second embodiment.

FIG. 10 is a schematic plan view illustrating a state in which the third collector electrode 31 illustrated in FIG. 9 is positionally shifted and overlappingly stacked on the first finger electrode 12. As illustrated in FIG. 10, the width W2 of the third collector electrode 31 is less than the width W1 of the first finger electrode 12. In this case, even if the third collector electrode 31 is positionally shifted, the stacked collector electrode is contained within the width W2, which prevents an increase in width of the overlappingly stacked collector electrode. Thus, this structure can suppress an increase in light-shielded area and can suppress a decrease in the short-circuit current Isc of the photoelectric conversion cell 1.

Like in the first embodiment, in the second embodiment, the third collector electrode 31 is preferably configured to be disposed in a region near the busbar electrode 13 of the finger electrode 12 and not to be disposed in a region far from the busbar electrode 13. A partial increase in thickness of the finger electrode 12 in a region near the busbar electrode 13 can reduce electrical resistance in a region with high current density while saving the amount of formation material.

In the first and second embodiments, the third collector electrode is formed in a position overlapping the first collector electrode on the first main surface of the photoelectric conversion cell 1. Note that the third collector electrode may be formed in a position overlapping the second collector electrode on the second main surface of the photoelectric conversion cell 1. Note also that if the third collector electrode is formed on the second main surface of the photoelectric conversion cell 1, the third collector electrode may be formed in a position not overlapping the second collector electrode.

If the third collector electrode is formed in a position not overlapping the second collector electrode, this structure can increase the area of the collector electrode on the second main surface 20 and thus can enhance current collecting properties of the second main surface 20.

In the first and second embodiments, the third collector electrode is formed on the first main surface, but the present disclosure is not limited to these embodiments. For example, the third collector electrode may be formed on both of the first main surface and the second main surface.

If the third collector electrode is formed only on the first main surface, the second collector electrode 21 provided on the second main surface need not be a comb teeth shaped electrode including the second finger electrode 22 and the second busbar electrode 23. For example, a thin film metal electrode covering substantially the entire surface of the second main surface of the photoelectric conversion cell 1 may be formed on the second main surface.

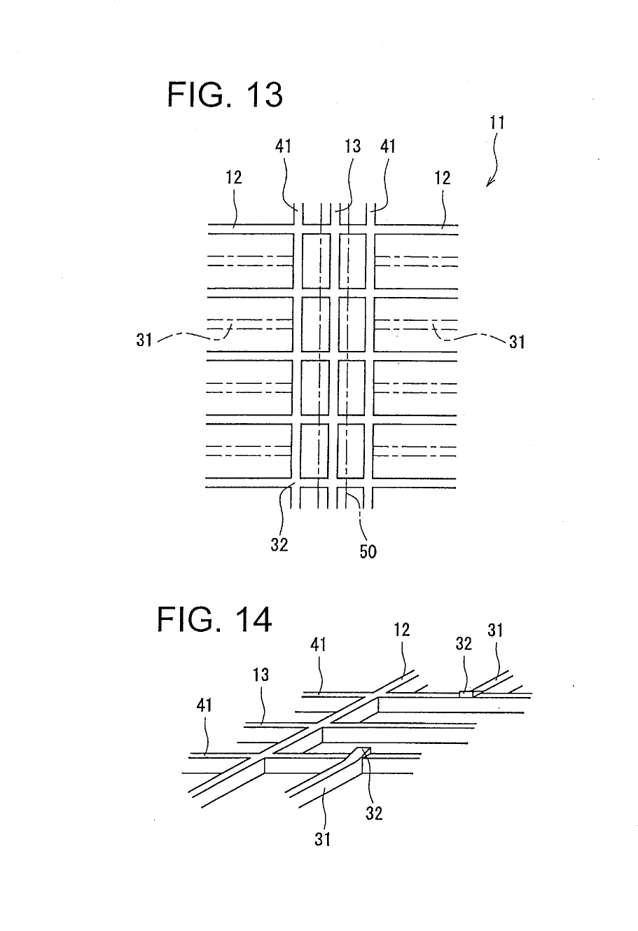

As illustrated in FIGS. 13 and 14, an auxiliary electrode 41 can be formed on the photoelectric conversion cell 1. In the examples in FIGS. 13 and 14, the auxiliary electrodes 41 and the third collector electrodes 31 are formed on the first main surface 10, but they may be formed on the second main surface 20 or may be formed on both surfaces. Here, the description focuses on an example of using the first main surface 10, but the following description can be similarly applied to an example of using the second main surface 20.

The first collector electrode 11 illustrated in FIGS. 13 and 14 includes a finger electrode 12 and a busbar electrode 13 which is formed to intersect the finger electrode 12 and to which a wiring material 50 (indicated by dot-and-dash lines) is attached when formed into a module. For example, two or three busbar electrodes 13 are formed substantially parallel to each other and a plurality of finger electrodes 12 are formed substantially perpendicular to the respective busbar electrodes 13. The first collector electrode 11 further includes an auxiliary electrode 41 which is formed to intersect each finger electrode 12 outside the range (region located immediately under the wiring material 50) in which the wiring material 50 is disposed. The auxiliary electrode 41 is formed along the busbar electrode 13, and is preferably formed substantially parallel to the busbar electrode 13.

When the third collector electrode 31 is formed based on the characteristic values of the photoelectric conversion cell 1, the auxiliary electrode 41 is connected to the third collector electrode 31. The embodiment illustrated in FIGS. 13 and 14 includes the auxiliary electrodes 41 to reduce electrode irregularities in the range in which the wiring material 50 is disposed. When the third collector electrode 31 is connected to the auxiliary electrode 41, the electrode height is locally increased at the connection portion 32 (see FIG. 14) and the wiring material 50 is not disposed on the connection portion 32.

The auxiliary electrodes 41 are formed, for example, simultaneously with the finger electrodes 12 and the busbar electrode 13, but may be formed simultaneously with the third collector electrode 31. In the latter case, the electrode height is locally increased at a connection portion between the finger electrode 12 and the auxiliary electrode 41, but the connection portion is also located outside the range in which the wiring material 50 is disposed.

The length of the auxiliary electrode 41 is not particularly limited, but preferably the auxiliary electrode 41 has substantially the same length as that of the busbar electrode 13 and is connected to all finger electrodes 12. Note that the number of auxiliary electrodes 41 is not particularly limited, but preferably two of the auxiliary electrodes 41 are provided for each busbar electrode 13, in such a manner that the two auxiliary electrodes 41 sandwich the busbar electrode 13. In other words, the auxiliary electrodes 41 are formed on opposite sides in the width direction of the busbar electrode 13.

The third collector electrode 31 is formed so as to be connected to the auxiliary electrode 41 without being connected directly to the busbar electrode 13 and so as to be connected to the busbar electrode 13 through the auxiliary electrode 41 and the finger electrode 12. In the examples illustrated in FIGS. 13 and 14, a third collector electrode 31 is formed substantially parallel to a finger electrode 12 between the adjacent finger electrodes 12. In other words, the third collector electrode 31 is formed in a position not overlapping the first collector electrode 11, but in the same manner as in the embodiments illustrated in FIGS. 5 to 10, the third collector electrode 31 may be formed in a position overlapping finger electrode 12. Preferably, one end of the third collector electrode 31 is connected to the auxiliary electrode 41 and is not formed in the range in which the wiring material 50 is disposed.

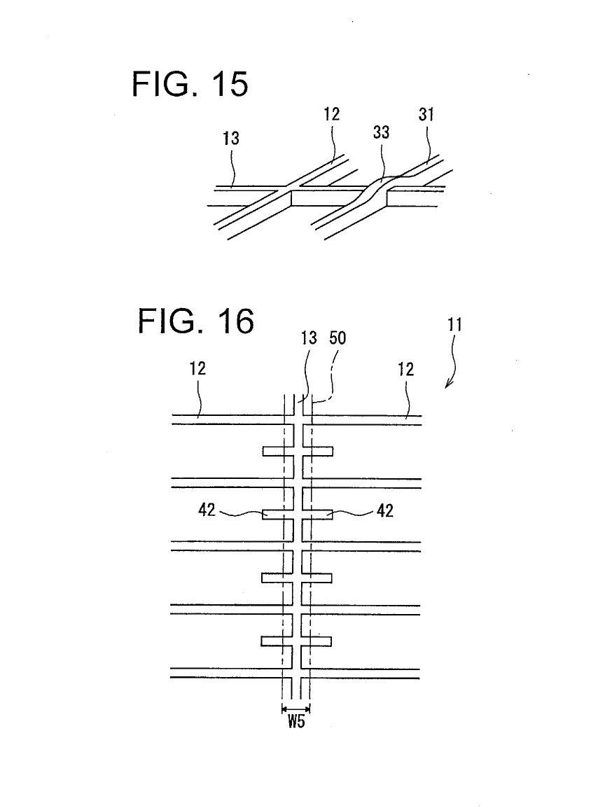

As illustrated in FIG. 15, the third collector electrode 31 may be formed in a region not overlapping the finger electrode 12 on the photoelectric conversion cell 1. In the example illustrated in FIG. 15, the third collector electrode 31 is formed on the first main surface 10, but instead may be formed on the second main surface 20 or may be formed on both surfaces. Here, the description provides an example of using the first main surface 10, but the following description may be similarly applied to another example of using the second main surface 20.

The first collector electrode 11 illustrated in FIG. 15 includes a finger electrode 12 and a busbar electrode 13 which is formed to intersect the finger electrode 12 and to which a wiring material 50 (not illustrated) is attached when formed into a module. For example, two or three busbar electrodes 13 are formed substantially parallel to each other and a plurality of finger electrodes 12 are formed substantially perpendicular to the respective busbar electrodes 13. The third collector electrode 31 is formed substantially parallel to the finger electrode 12 including the range (region located immediately under the wiring material 50) in which the wiring material 50 is disposed. The third collector electrode 31 is overlappingly stacked on the busbar electrode 13 at the connection portion 33 to form a region with a locally high electrode.

As illustrated in FIG. 15, when the third collector electrode 31 is connected to the busbar electrode 13, the electrode height is locally increased at the connection portion 33. When the wiring material 50 is pressure-bonded on the busbar electrode 13, the connection portion 33 contacts the wiring material 50. At this time, the surface area of the busbar electrode 13 is increased by the connection portion 33 with a locally increased height, which improves adhesion to the wiring material 50. Such a configuration is suitable for connecting the busbar electrode 13 to the wiring material 50 using a resin adhesive including epoxy resin, acrylic resin, or urethane resin as described in Japanese Patent Laid-Open Publication No. 2009-158858. An improvement in the adhesion between the connection portion 33 and the wiring material 50 can increase connection reliability between the busbar electrode 13 and the wiring material 50.

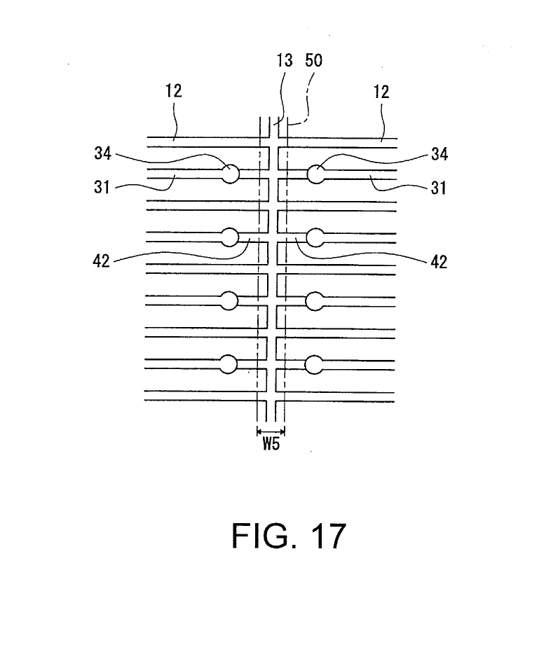

As illustrated in FIGS. 16 and 17, a connection electrode 42 may be formed on the photoelectric conversion cell 1. In the example illustrated in FIGS. 16 and 17, the connection electrode 42 and the third collector electrode 31 are formed on the first main surface 10, but instead may be formed on the second main surface 20 or may be formed on both surfaces. Here, the description provides an example of using the first main surface 10, but the following description may be similarly applied to another example of using the second main surface 20.

The first collector electrode 11 illustrated in FIGS. 16 and 17 includes finger electrodes 12 and a busbar electrode 13 in the same manner as in the embodiments illustrated in FIGS. 13 and 14. The first collector electrode 11 includes a connection electrode 42 extending from the busbar electrode 13 to outside the range in which the wiring material 50 is disposed. The connection electrode 42 is formed along the finger electrode 12, and preferably formed substantially perpendicular to the busbar electrode 13 and substantially parallel to the finger electrode 12. Note that the connection electrode 42 is shorter than the finger electrode 12. The connection electrode 42 is preferably formed with a length equivalent to the width W5 of the wiring material 50 or in a range of length equal to or greater than W5 to equal to or less than twice W5, in consideration of the material cost, shadow loss, positional shifting of the wiring material 50, and the like.

The number of connection electrodes 42 is not particularly limited, but for example, is the same as the number of finger electrodes 12. In the example illustrated in FIG. 16, the connection electrodes 42 are formed one between every adjacent finger electrode 12, but no connection electrode 42 may be formed between the adjacent finger electrodes 12, and two or more connection electrodes 42 may be formed between the adjacent finger electrodes 12. The connection electrode 42 is preferably formed simultaneously with the finger electrode 12 and the busbar electrode 13.

When the third collector electrode 31 is formed based on the characteristic values of the photoelectric conversion cell 1, the connection electrode 42 is connected to the third collector electrode 31. The third collector electrode 31 is formed to be connected to the connection electrode 42, but not to be connected to the busbar electrode 13. When the third collector electrode 31 is connected to the connection electrode 42, the electrode height is locally increased at the connection portion, but the wiring material 50 is not disposed on the connection portion.

A widened portion 34 with a wider portion than the other portion is formed at an end portion of the third collector electrode 31. The third collector electrode 31 is preferably formed on the same straight line as the connection electrode 42, but the third collector electrode 31 may be formed shifted from the straight line. Even if the third collector electrode 31 is formed to be positionally shifted, the widened portion 34 enables reliable connection between the third collector electrode 31 and the connection electrode 42. Note that a widened portion may be provided at an end portion of the connection electrode 42, or instead, the connection electrode 42 may be widened, but in terms of reducing the material cost and the like, the widened portion 34 is preferably provided on the third collector electrode 31 side to be printed for the second time.

In the example illustrated in FIG. 17, the third collector electrode 31 is formed substantially parallel to the finger electrode 12 between the adjacent finger electrodes 12. In other words, the third collector electrode 31 is formed in a position not overlapping the first collector electrode 11, but in the same manner as in the embodiments illustrated in FIGS. 5 to 10, the third collector electrode 31 may be formed in a position overlapping the finger electrode 12.

Note that in the step of manufacturing the solar cell module by attaching the wiring material 50 to the photoelectric conversion cell 1, the wiring material 50 is preferably disposed by bypassing the connection portion between the first-time printed electrode (first collector electrode 11) and the second-time printed electrode (third collector electrode 31). This step suppresses cracking of the photoelectric conversion cell 1 and improves the yield of modules.

In the above embodiments, the first main surface has been described as the light receiving surface and the second main surface has been described as the rear surface, but instead the second main surface may serve as the light receiving surface and the first main surface may serve as the rear surface.

### REFERENCE SIGNS LIST

1 photoelectric conversion cell
10 first main surface
11 first collector electrode
12 first finger electrode
13 first busbar electrode
20 second main surface
21 second collector electrode
22 second finger electrode
23 second busbar electrode
31 third collector electrode
32,33 connection portion
34 widened portion
41 auxiliary electrode
42 connection electrode
51 current measuring pin-like terminal
52 voltage measuring pin-like terminal
61 current measuring block-like terminal
62 voltage measuring block-like terminal
63 insulator

What is claimed is:

1. A solar cell manufacturing method comprising:
a step of preparing a photoelectric conversion cell having a first main surface and a second main surface;
a step of forming a first collector electrode on the first main surface and forming a second collector electrode on the second main surface;
a step of measuring characteristic values of the photoelectric conversion cell having the first collector electrode and the second collector electrode thereon; and
a step of forming a third collector electrode on at least one of the first main surface and the second main surface based on the characteristic values.

2. The solar cell manufacturing method according to claim 1, wherein the third collector electrode is formed for the photoelectric conversion cell where the characteristic values satisfy a predetermined criterion.

3. The solar cell manufacturing method according to claim 1, wherein the third collector electrode is formed so as to at least partially overlap the first collector electrode on the first main surface.

4. The solar cell manufacturing method according to claim 3, wherein the first collector electrode has a width less than the width of the third collector electrode.

5. The solar cell manufacturing method according to claim 3, wherein the third collector electrode has a width less than the width of the first collector electrode.

6. The solar cell manufacturing method according to of claim 1, wherein the third collector electrode is formed so as to at least partially overlap the second collector electrode on the second main surface.

7. The solar cell manufacturing method according to claim 6, wherein the second collector electrode has a width less than the width of the third collector electrode.

8. The solar cell manufacturing method according to claim 6, wherein the third collector electrode has a width less than the width of the second collector electrode.

9. The solar cell manufacturing method according to claim 1, wherein the third collector electrode is formed in a position not overlapping at least one of the first collector electrode on the first main surface and the second collector electrode on the second main surface.

10. The solar cell manufacturing method according to claim 1, wherein the characteristic values are measured by a four-terminal method by bringing a plurality of current measuring terminals and a plurality of voltage measuring terminals into contact with the first collector electrode and the second collector electrode respectively.

11. The solar cell manufacturing method according to claim 10, wherein the current measuring terminal and the voltage measuring terminal contacting the first collector electrode are pin-like terminals that can independently abut against the respective collector electrodes; and the current measuring terminal and the voltage measuring terminal contacting the second collector electrode are block-like terminals where each of the blocks is alternately connected to each other with an insulator interposed therebetween.

12. The solar cell manufacturing method according to claim 10, wherein a circuit connecting the voltage measuring terminal to a voltmeter includes therein a resistor having a resistance that is greater than the resistance of the first collector electrode and the second collector electrode contacting the terminals.

13. The solar cell manufacturing method according to claim 11, wherein
the step of measuring the characteristic values of the photoelectric conversion cell comprises:
a step of causing the block-like current measuring terminal and the block-like voltage measuring terminal to be continuously in contact with the second collector electrode and causing the pin-like current measuring terminal and the pin-like voltage measuring terminal to be in discrete contact with the first collector electrode; and
a step of measuring the characteristic values using the block-like current measuring terminal and the block-like voltage measuring terminal, and the pin-like current measuring terminal and the pin-like voltage measuring terminal.

14. The solar cell manufacturing method according to claim 1, wherein
at least one of the first collector electrode and the second collector electrode includes a finger electrode, a busbar electrode which is formed to intersect the finger electrode and to which a wiring material is attached when formed into a module, and an auxiliary electrode which is formed to intersect the finger electrode outside a range in which the wiring material is disposed, and
the third collector electrode is formed to be connected to the auxiliary electrode, but not to be connected to the busbar electrode.

15. The solar cell manufacturing method according to claim 1, wherein
at least one of the first collector electrode and the second collector electrode includes a finger electrode, a busbar electrode which is formed to intersect the finger electrode and to which the wiring material is attached when formed into a module, and a connection electrode extending from the busbar electrode to outside the range in which the wiring material is disposed, and
the third collector electrode is formed to be connected to the auxiliary electrode, but not to be connected to the busbar electrode.

16. The solar cell manufacturing method according to claim 1, wherein the first main surface is a light receiving surface and the second main surface is a rear surface.
